(19) United States
(12) Patent Application Publication
(10) Pub. No.: US 2012/0098164 A1
(43) Pub. Date: Apr. 26, 2012

(54) TWO-PHOTON STEREOLITHOGRAPHY USING PHOTOCURABLE COMPOSITIONS

(76) Inventors: Shyi-Herng Kan, Singapore (SG); Tseng-Ming Hsieh, Singapore (SG); Jackie Y. Ying, Singapore (SG)

(21) Appl. No.: 12/669,461

(22) PCT Filed: Jul. 21, 2008
(86) PCT No.: PCT/SG08/00264

§ 371 Date: Aug. 20, 2010

Related U.S. Application Data
(60) Provisional application No. 60/929,972, filed on Jul. 20, 2007.

(51) Int. Cl. H01J 37/30

(52) U.S. Cl. 264/494

(57) ABSTRACT

Two-photon stereolithography can be performed using a photocurable material comprising a poly(meth)acrylate having a (meth)acrylate functionality of at least 3 and a molecular weight (MW) of at least 650, a urethane(meth)acrylate having a (meth)acrylate functionality of 2 to 4 and a MW of 400 to 10,000, a di(meth)acrylate made from bisphenol A or bisphenol F; and a photoinitiator. A beam of light is focused to a focus region of the material to induce two-photon absorption in the focus region, and thus polymerization of the material in the focus region. The beam is scanned across said material according to a pre-selected pattern so that the beam is focused to different pre-selected regions, to induce polymerization of the material at the pre-selected regions.

### CROSS-REFERENCE TO RELATED APPLICATION

This application claims the benefits of U.S. provisional application No. 60/929,972, filed Jul. 20, 2007, the contents of which are incorporated herein by reference.

This application is related to PCT application entitled “Device and Method for Focusing a Beam of Light with Reduced Focal Plane Distortion”, filed by the same applicants concurrently with the present application, the contents of which are incorporated herein by reference.

### FIELD OF THE INVENTION

The present invention relates to methods of two-photon stereolithography, particularly two-photon stereolithography using photocurable compositions.

### BACKGROUND OF THE INVENTION

Two-photon stereolithography is an emerging and promising technology, with many potential applications, such as in the semiconductor industry, for photonics devices, in the wireless industry, for microelectromechanical systems (MEMS) or nanoelectromechanical systems (NEMS), in the rapid prototyping industry, in tissue engineering, and in the chemical and pharmaceutical industries. Two-photon stereolithography (e.g. two-photon polymerization) utilizes localized two-photon absorption/excitation to induce structural changes in a target. However, not all materials are suitable for two-photon stereolithography. Only in certain materials, two-photon absorption induced polymerization can proceed at a sufficient rate to be of practical use for two-photon stereolithography.

### SUMMARY OF THE INVENTION

In accordance with an aspect of the present invention, there is provided a method of processing a material to form a three-dimensional article, comprising providing a photocurable material comprising a poly(meth)acrylate having a (meth)acrylate functionality of at least 3 and a molecular weight (MW) of at least 650, a urethane(meth)acrylate having a (meth)acrylate functionality of 2 to 4 and a MW of 400 to 10,000, a di(meth)acrylate made from bisphenol A or bisphenol F; and a photoinitiator; focusing a beam of light to a focus region of the material to induce two-photon absorption in the focus region, and thus polymerization of the material in the focus region; and scanning the beam across the material according to a pre-selected pattern so that the beam is focused to different pre-selected regions, to induce polymerization of the material at the pre-selected regions.

An un-polymerized portion of the material may be removed from a polymerized portion of the material, to form the three-dimensional article. The material may comprise 2 to 20 wt % of the poly(meth)acrylate, 20 to 60 wt % of the urethane(meth)acrylate, 20 to 80 wt % of the di(meth)acrylate, and 0.1 to 10 wt % of the photoinitiator. The poly(meth)acrylate may have a MW in the range of 880 to 1200. The material may comprise 5 to 18 wt % of the poly(meth)acrylate. The material may comprise 20 to 50 wt % of the urethane(meth)acrylate. The material may comprise 35 to 55% of the di(meth)acrylate. The material may comprise 2 to 8 wt % of the photoinitiator. The material may comprise 8 to 16 wt % of the poly(meth)acrylate, 25 to 45 wt % of the urethane(meth)acrylate, 40 to 50 wt % of the di(meth)acrylate, and 3 to 7 wt % of the photoinitiator. The di(meth)acrylate may be monomeric or oligomeric. The di(meth)acrylate may be a mixture of ethoxylated bisphenol A diacrylate and ethoxylated bisphenol A dimethacrylate. The beam may be scanned according to a first pre-selected pattern to induce polymerization at pre-selected regions within a first layer, and subsequently scanned beam according to a second pre-selected pattern to induce polymerization at pre-selected regions within a second layer. The first pattern and the second pattern may be different or identical. The scanning may be repeated to polymerize selected regions in more than two layers of the material. The beam may have a spot size of about 2 μm or less at the focus region. The focus region may have a volume of about 10⁻¹² cm³ or less.

Other aspects and features of the present invention will become apparent to those of ordinary skill in the art upon review of the following description of specific embodiments of the invention in conjunction with the accompanying figures.

### BRIEF DESCRIPTION OF THE DRAWINGS

In the figures, which illustrate, by way of example only, embodiments of the present invention,

FIG. 1 is a schematic diagram of a two-photon stereolithography apparatus;

FIG. 2 is a schematic side view of the objective lens, target and support shown in FIG. 1;

FIG. 3 is a scanning electron microscopy (SEM) image of a top view of an article formed by two-photon polymerization using the apparatus of FIG. 1 and a composition exemplary of an embodiment of the present invention;

FIG. 4 is an SEM image of a perspective view of the article of FIG. 3 in a different state;

FIG. 5 is an SEM image of a perspective view of a second article having an array of unit devices, formed by two-photon polymerization using the apparatus of FIG. 1 and a composition exemplary of an embodiment of the present invention; and

FIG. 6 is an SEM image of a top plan view of a unit device on the article shown in FIG. 5.

### DETAILED DESCRIPTION

In exemplary embodiments of the present invention, a liquid composition comprising a poly(meth)acrylate, a urethane(meth)acrylate, a di(meth)acrylate, and a photo-initiator, is used for two-photon stereolithography. The poly(meth)acrylate has a (meth)acrylate functionality of at least 3 and a molecular weight (MW) of at least 650. The urethane(meth)acrylate has a (meth)acrylate functionality of 2 to 4 and a MW of 400 to 10,000. The di(meth)acrylate is made from bisphenol A or bisphenol F; and a photoinitiator.

In different embodiments, the composition may comprise 2 to 20 wt % (weight percent) of poly(meth)acrylate, 20 to 60 wt % of urethane(meth)acrylate, 20 to 80 wt % of di(meth)acrylate, and 0.1 to 10 wt % of photoinitiator.

In one embodiment, the poly(meth)acrylate may have a MW in the range of 880 to 1200.

In some embodiments, the composition material may include 5 to 18 wt % of poly(meth)acrylate, 20 to 50 wt % of urethane(meth)acrylate, 35 to 55 wt % of di(meth)acrylate, or 2 to 8 wt % of photoinitiator. In one embodiment, the material comprises 8 to 16 wt % of poly(meth)acrylate, 25 to 45 wt % of urethane(meth)acrylate, 40 to 50 wt % of di(meth)acrylate, and 3 to 7 wt % of photoinitiator.

The poly(meth)acrylate may include a tri-, tetra-, or penta-(meth)acrylate. The di(meth)acrylate may be monomeric or oligomeric, and may be a mixture of ethoxylated bisphenol A diacrylate and ethoxylated bisphenol A dimethacrylate.

The composition may also include a surfactant.

The composition may include a photocurable composition described in U.S. Pat. No. 6,025,114, the contents of which are incorporated herein by reference.

In an exemplary embodiment of the present invention, the composition may contain a selective combination of the following commercially available materials, where the texts in parentheses indicate exemplary product names and suppliers:
ethoxylated bisphenol A dimethacrylate (SR-348, Sartomer™);
ethoxylated bisphenol A diacrylate (SR-349, Sartomer);
ethoxylated 1,1,1-trimethylopropane triacrylate (SR-9035, Sartomer);
UV photoinitiator DAR1173 with a formula of Ph-CO—C(CH₃)₂OH
2,2-dimethoxy-2-phenylacetophenone (Irgacure 651, Ciba Geigy™, referred to herein as IRG);
aliphatic urethane acrylate (EB-270, UCB Chemicals™);
silicone surfactant (DC190, Dow Corning™);
Urethane acrylate (NR-2720, Zeneca Resins™).

In some embodiments of the present invention, the composition may include a mixture listed in Tables I and II.

TABLE I
Mixtures for two-photon lithography

| | | | NR- | | DAR- | | |
|---|---|---|---|---|---|---|---|
| Mixture | SR-349 | SR-348 | 2720 | SR-9035 | 1173 | DC190 | IRG |
| 1 | 8.0 | 42.0 | 34.5 | 10.0 | 5.5 | — | — |
| 2 | — | 45.0 | 34.5 | 15.0 | 5.5 | — | — |
| 3 | 8.0 | 42.0 | 34.5 | 10.0 | 5.5 | 0.2 | — |
| 4 | — | 45.0 | 34.5 | 15.0 | 5.5 | 0.2 | — |
| 5 | 20.0 | 35.0 | 29.0 | 10.5 | 5.5 | — | — |
| 6 | 20.5 | 35.9 | 29.8 | 10.8 | 5.5 | — | 3.0 |

TABLE II
Mixtures for two-photon lithography

| | | | NR- | | DAR- | | |
|---|---|---|---|---|---|---|---|
| Mixture | SR-349 | SR-348 | 2720 | SR-9035 | 1173 | IRG | EB-270 |
| 7 | 15.0 | 46.0 | 24.0 | 9.5 | 5.5 | — | — |
| 8 | 10.0 | 40.0 | 25.0 | 19.5 | 5.5 | — | — |
| 9 | 19.0 | 44.0 | 21.0 | 11.0 | 5.0 | — | — |
| 10 | 4.5 | 40.0 | 40.0 | 10.0 | 5.5 | — | — |
| 11 | — | 42.0 | 42.0 | 10.5 | 5.5 | — | — |
| 12 | — | 49.9 | 30.2 | 14.4 | 5.6 | — | — |
| 13 | — | 45.5 | 34.5 | 15.0 | 5.0 | — | — |
| 14 | 55.0 | — | 29.0 | 10.5 | 5.5 | — | — |
| 15 | 55.0 | — | 29.0 | 10.5 | — | 5.5 | — |
| 16 | 56.6 | — | 29.8 | 10.8 | — | 2.8 | — |
| 17 | 20.5 | 35.9 | 29.8 | 10.8 | — | 3.0 | — |
| 18 | 10.9 | 36.6 | — | 12.5 | 5.5 | — | 34.5 |
| 19 | — | 50.0 | — | 19.5 | 5.5 | — | 25.0 |

While not all photocurable materials are suitable for fabricating articles by two-photon stereolithography, the compositions described above may be formed into 3D articles according to a two-photon stereolithography process described next.

In one embodiment, a material formed of the composition described above can be processed to form 3D particles by focusing a beam of light to a focus region in the material to induce two-photon absorption in the focus region, and thus polymerization of the material in the focus region. As two-photon absorption is limited to a small region, the material in the areas outside the focus region will not be polymerized. The light beam is scanned across the material according to a pre-selected pattern so that the beam is focused to different pre-selected regions in the material to induce polymerization of the material at the pre-selected regions. The beam may be scanned across a transversal plane that is perpendicular to an axis, such as the optical axis of the focusing device that focuses the beam onto the material. Once the scan in one layer of the material is completed, the target material may be moved relative to the focusing device to scan another layer according to a pre-selected pattern which may be different from or the same as the pattern for the previous layer. The scanning may be repeated to polymerize selected regions of the material in more than two layers, layer-by-layer. Thus, different regions in the material are polymerized according to a pre-selected design. The material in the polymerized region may be hardened and solidified. Thus, in one embodiment, the un-polymerized portions of the material may be removed from the polymerized portion of the material and the polymerized portion of the material forms a 3-D article. Depending on the application and the material used, in some embodiments, the polymerized portions may be removed from the un-polymerized portions and the un-polymerized portion forms the product article. The removed portions can be removed after completion of the scanning of a layer and before scanning the next layer, or after all layers have been scanned.

Removal or separation of one portion of the material from the other may be performed using any suitable technique, depending on the particular application. In one embodiment, two-photon absorption will induce certain chemical reactions in the selected regions of the material. The chemical reactions result in a new material. The new material and the original material will have different chemical or physical properties. Thus, the removal or separation of the materials may be performed based on the differences. For example, if one material is a liquid and the other is a solid, they may be readily separated. In other cases, one material may be soluble and the other may be insoluble in a particular solvent. Thus, the soluble one may be removed by washing using the solvent. In some cases, one material may also be easily removed by another technique, while the other material is substantially unaffected by that technique.

With two-photon lithography, a liquid target material can be formed into a 3D article by scanning the liquid material contained in a container. It is not necessary to form the article by scanning an initial layer of liquid to first form a solid bottom layer and then add more liquid on top of the solid layer to form the next layer, which would be necessary if the material is to be cured by single-photon lithography. As two-photon absorption can occur only within a limited portion of the beam path at a selected depth in the target material, the target material may be formed layer-by-layer without having to add new liquid material during the scan. Thus, production rate can be much higher.

Further, with two-photon stereolithography, some potential problems arising from adding new liquid to a solid substrate, such as insufficient cross-linking between the adjacent layers may be avoided.

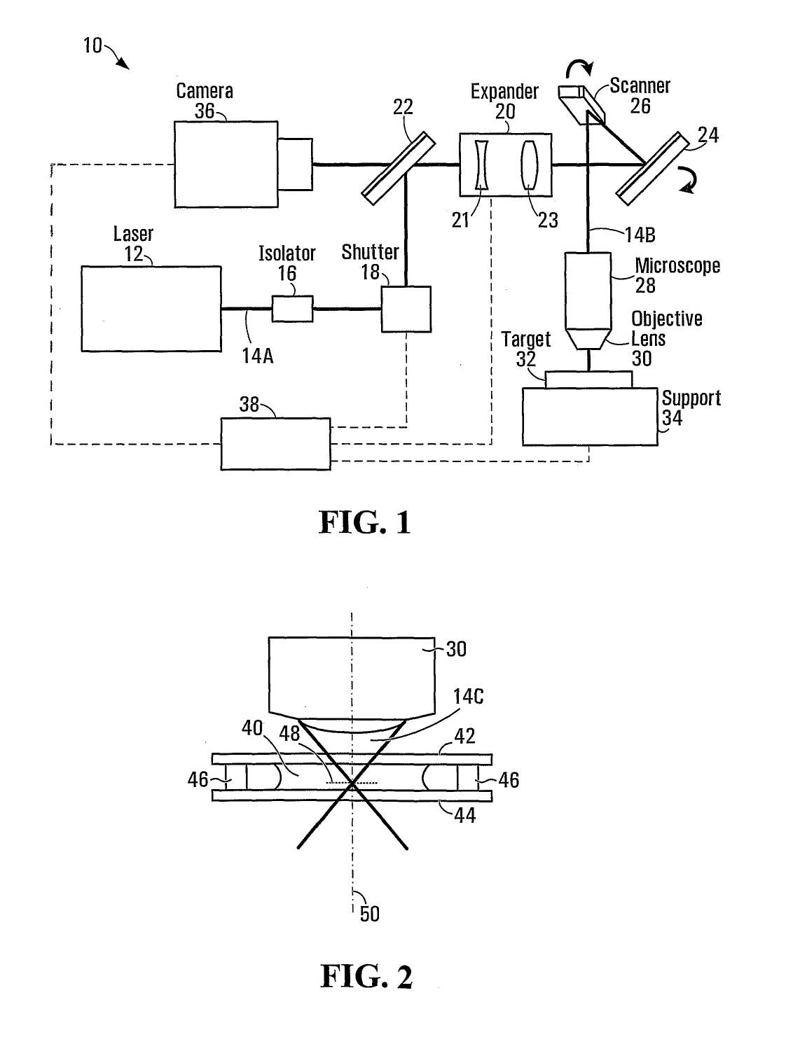

FIG. 1 is a schematic diagram illustrating a system 10 for two-photon stereolithography, which can be used to treat the above compositions according an exemplary embodiment of the present invention.

System 10 includes a light source for emitting a beam of photons, such as laser source 12. In this embodiment, laser source 12 is a pulsed tunable near-infrared laser, such as a Ti-sapphire laser. A commercially available laser source, such as the Spectra Physics Mai Tai™ broadband Ti-sapphire laser may be used. The pulse rate may be of the order of femtosecond. Other suitable lasers may be used in other embodiments.

Laser source 12 is used to produce a beam 14A of laser light. The wavelength of the laser light (photons) is selected to induce two-photon absorption in the particular target material. For example, if a single-photon absorption wavelength for the particular material is L₁, the wavelength for two-photon absorption may be 2L₁. In order to work with different materials, laser source 12 can be tuned in wavelength within a given range. For example, to use two-photon absorption to activate UV polymerization in a material where the required absorption energy quantum is about 355 nm, the spectrum of the light may have a peak at about 710 nm.

In this embodiment, the laser wavelength is tunable between about 700 to about 1020 nm. The output beam diameter from laser source 12 is less than 2 mm with a focusing diameter of 1/e². The full far field divergence angle of the beam is less than about 1 mrad. In the pulsed mode, the average output power of laser source 12 is larger than 2.5 W, and the peak power is larger than 310 kW. In different embodiments, the average laser output power may be from about 50 mW to about 4 W. A higher laser power may be used with a dry objective lens and may be desirable as it can provide higher scanning speed and throughput. In the present embodiment, the pulse repetition rate may be about 80 MHz, and the pulse width may be about 100 fs.

In another embodiment, beam 14A emitted from laser source 12 may have a beam width of less than about 1.2 mm with a focusing diameter of 1/e². In some embodiments, a smaller beam diameter may be advantageous as it can provide a higher resolution.

An isolator 16 is positioned adjacent to laser source 12 in the path of the beam 14A to isolate laser source 12 from reflected laser light. That is, isolator 16 is configured and positioned to prevent reflected laser light to re-enter laser source 12, as reflected light may disrupt the mode locking operation of the laser. In this embodiment, isolator 16 is a broadband isolator. For example, a 10-5-NIR-HP™ isolator from Optics For Research™ (OFR) may be used. In other embodiments, other suitable laser light isolator may be used.

A shutter 18 is positioned downstream of isolator 16 for selectively transmitting, beam 14A therethrough. Shutter 18 is an Acousto-Optic Modulator (AOM) in this embodiment, which provides fast-shutter operation. For example, an AA MOD 110 shutter from AA Opto-Electronic™ may be used.

In other embodiments, shutter 18 may be placed elsewhere, such as further downstream, and may be any other suitable high-speed shutter for the specific application. For example, the shutter speed may be on the order of about 100 MHz.

An optical beam expander 20 is positioned downstream of shutter 18, and is configured to expand beam 14A and produce a collimated beam 14B with an increased beam width (beams 14A and 14B, as well as 14C shown FIG. 2, are also collectively referred to as beam 14). As used herein, a collimated beam refers to a beam that has a low divergence. For example, in some embodiments, the divergence of the collimated beam 14B may be less than about 7.6 mrad. As can be appreciated, a perfectly collimated beam of light (with divergence of zero) is difficult or impossible to obtain in practice. Further, the divergence of the collimated beam 14B is varied during use and may deviate from the lowest divergence achievable for a given optical setup.

A dichroic mirror 22 may be provided to reflect beam 14A into expander 20.

Expander 20 includes an expansion lens 21 for expanding the beam diameter to a large enough size so that the beam diameter is larger than the input aperture (not separately shown) of the focusing device such as microscope 28, so that the back of the objective lens 30 (see below) is overfilled to make full use of the objective aperture. Expansion lens 21 is a diverging lens, also referred to as a negative, concave or dispersing lens. For expansion lens 21, the lens surfaces may be plano-concave, double (bi) concave or concavo-convex.

Expander 20 also includes an expander objective lens 23 positioned downstream of expansion lens 21. Expander objective lens 23 is a converging lens, also referred to as a positive, convex lens. The lens surfaces of a converging lens may be plano-convex, bi-convex or meniscus. The beam size of beam 14 can be increased after passing through expander 20.

Expander 20 is electronically controlled to expand and collimate beam 14. Expander 20 increases the beam diameter to a desired size and is also configured to automatically adjust the divergence (collimation) of beam 14B for correcting focal plane distortion, which is mainly due to field curvature effect, as will be further explained below.

In this embodiment, expansion lens 21 is axially moved/adjusted by a motorized translator (not separately shown) to vary or adjust the distance between expansion lens 21 and expander objective lens 23. The distance adjustment is automated. As such, beam expander 20 also acts as an on-the-fly focusing module to automatically correct for any focal plane distortion, which may occur such as when large lens elements that do not correct for plane distortion are used. The physical distance between expansion lens 21 and expander objective lens 23 may be increased or decreased from a balanced distance, such as 90 mm, to change the beam size/diameter, or to reduce plane distortion. For example, one of the lenses 21 and 23 may be repositionable. The movement of the movable lens may be driven by a motor. Distance adjustment may also be made by changing the optical distance between the two lenses without changing the physical distance therebetween in a different embodiment.

In one embodiment, the diameter of the collimated beam 14B may be about 10 mm, and the distance between lenses 21 and 23 (thus divergence of beam 14B) may be adjusted so that the diameter of beam 14B may be varied to a few mm above or below 10 mm at the input aperture of microscope 28.

In system 10, expander 20 includes a varioSCAN 20™, provided by Scanlab AG™. This device may be controlled using an RTC™ control board and control software provided by the same company. Details of construction and operation of varioSCAN 20™ can be obtained from Scanlab, such as from its website: www.scanlab.de/. In other embodiments, varioSCAN 20™ may be replaced with another suitable expander and dynamic focusing device.

A mirror 24 is placed downstream of expander 20 to direct expanded collimated beam 14B into a scanner 26.

Scanner 26 re-directs beam 14B to scan beam 14B over a desired target region. A galvanometer scanner may be used as scanner 26. For example, the scanner may be a ScanCube7™ scanner provided by Scanlab. In a typical galvanometer scanner, two scan mirrors (not separately shown) may be provided, each driven by a galvanometer. Each scan mirror is independently adjusted (turned) to redirect the beam in one dimension. Thus, the two scan mirrors in combination can scan the beam across a two-dimensional plane.

A focusing device, such as a microscope 28, is placed downstream of scanner 26. Except the features expressly described herein, microscope 28 is otherwise a conventional microscope and can be constructed using conventional technology. Microscope 28 is positioned and configured to focus beam 14B onto a focal plane in a focus region of a target material.

Microscope 28 has a dry objective lens 30. A dry objective lens does not need to be immersed in oil or water to function properly. A dry objective lens can properly function when it is immersed in air or another gas environment. In this embodiment, a Nikon™ ELWD air objective is used. In other embodiments, other types of dry objectives may be used. Suitable Nikon ELWD air objectives include objectives that have magnification factors of 20× to 100×, such as 20×, 50×, and 100×. The numerical apertures (NA) of these objective lens are 0.4, 0.55, and 0.8, respectively. The 3-D resolution of these objective lens are respectively 1×1×7, 0.5×0.5×1, and 0.1×0.1×1, respectively (all in micron). The NA in dry objective lens 30 may vary from about 0.4 to about 0.9.

Objective lens 30 focuses beam 14B onto a focal point (focus region) in target 32.

Target 32 is supported by a support 34, which includes an adjustment mechanism, such as a high-resolution stage or a galvanometer.

Support 34 may move and adjust the position of target 32 in three (3) dimensions. Support 34 may be motorized for moving the target. Support 34 can move target 32 at least along the axial direction of beam 14. Optionally, support 34 may be configured to also move target 32 in transversal directions. In some embodiments, support may be configured to provide both translational and rotational movement of target 32.

A camera 36 such as a CCD (charge-coupled device) camera is provided for taking images of the processed target and monitoring the operation of apparatus 10. Camera 36 may be positioned to receive light from mirror 22.

A controller 38 may be provided for controlling the operation of apparatus 10. Controller 38 is in communication with expander 20 for controlling the automatic adjustment of the distance between expansion lens 21 and expander objective lens 23 to reduce distortion (curvature) of the focal plane of microscope 28. Controller 38 may also be in communication with one or more of laser source 12, shutter 18, scanner 26, support 34, and camera 36, to receive input therefrom, and may optionally control the operation thereof. The distance adjustment may be controlled based, at least in part, on the position or location of the current beam waist, or on the position/angles of the scan mirrors in the scanner which determines the direction of the beam axis. For each given beam direction, a length value may be stored in a memory in association with the beam direction or the expected coordinates of the location of the beam waist. The distance between lenses 21 and 23 is set to the corresponding length associated with that location when the beam is scanned toward that location. In this regard, controller 38 may be in communication with both expander 20 and scanner 26 to synchronize the movement of the motorized lens in expander 20 and the scan mirrors in scanner 26.

Controller 38 may include a computer or other computing devices and may also include software for controlling the operation of apparatus 10. The control software may include a modified SCAPS program. This program can synchronize the motion of a support stage and the beam scanning and can perform slide by slide scanning.

Controller 38 may be an integrated device or be provided as multiple separated units.

In this embodiment, system 10 has a scan speed of up to 30 mm/s and a scan height of up to 30 mm. The scan speed and scan height may be higher in other embodiments depending on the components used.

FIG. 2 schematically shows objective lens 30 and target 32, in more detail. In this embodiment, target 32 includes a target material 40 sandwiched between a top plate 42 and a bottom plate (or substrate) 44. Top plate 42 and bottom plate 44 are spaced apart by spacers 46.

As illustrated in FIG. 2, at the focal point of the focused beam 14C, the beam radius/diameter or width of beam 14C is at the minimum (referred to as the beam's spot size). This portion of beam 14C is referred to as its beam waist. In an embodiment of the present invention, when the incident angle of beam 14B at microscope 28 is varied by scanner 26, the focal point or beam waist of focused beam 14C also moves within or close to a focal plane 48, which is perpendicular to the optical axis 50 of objective lens 30, due to automatic correction of the focal plane distortion provided by the dynamic adjustment of the distance between lenses 21 and 23.

In an embodiment of the present invention, the distance between lenses 21 and 23 is dynamically adjusted to keep the beam waist of focused beam 14C remain substantially in focal plane 48, as will be further described below.

In use, system 10 is operated as follows.

A beam of laser 14 is produced by laser source 12. The beam has a sufficiently high peak and average power, such as larger than 310 kW and 2.5 W respectively. Beam 14 has no wavelength that will cause single photon photochemical reaction in the target material 40, and includes a wavelength that is suitable for triggering or inducing two-photon photochemical reaction in target material 40. Thus, the spectrum of beam 14 may be a narrow band centered at a desired wavelength or may have a single wavelength. The central wavelength may be in the range of about 700 to about 1020 nm depending on the target material and the reactions that are to be photo-initiated.

Beam 14A passes through isolator 16 and then shutter 18. Isolator 16 prevents any reflected light from getting into laser source 12, and can thus prolong the lifetime of laser source 12. Shutter 18 is controlled by controller 38 to selectively stop passage of beam 14 therethrough. The maximum shutter speed may be below 110 MHz in some applications.

Beam 14A is directed by mirror 22 to expander 20. Expander 20 produces an expanded and collimated beam 14B. The beam width of beam 14B is larger than the beam width of beam 14A, for example, by about 4 to about 10 times. The beam width of beam 14B may be selected to balance a number of factors and considerations. For example, higher expansion may be advantageous for reducing the moving distance of motorized lens in expander 20. On the other hand, a larger expansion may result in a larger power loss, such as when the beam width is wider than the diameter of the input aperture in microscope 28. Beam 14 passes through, in order, expansion lens 21 and focusing lens 23.

The expanded beam 14B is directed to scanner 26 by mirror 24.

Scanner 26 re-directs and scans beam 14B onto target 32 through microscope 28 and objective lens 30. Beam 14B is focused by objective lens 30 onto a confined volume, the focus region, in target material 40 which is held in position by plates 42 and 44 and support 34. Dry objective lens 30 is not immersed in any liquid during use but is exposed to air (or another gas).

The objective lens 30 focuses expanded and collimated beam 14B into a focus region in the target material 40. When large optical elements are used, the beam waist of focused beam 14C can significantly deviate from the focal plane 48 of objective lens 30. That is, the focal plane distortion at off-axis locations can be significant so as to substantially affect the shape of the product formed. Ideally, beam 14 should be focused onto focal plane 48 regardless of whether its path is near or away from optical axis 50 of objective lens 30. In practice, it may be acceptable that the beam waist is kept sufficiently close to a plane 48 (i.e. substantially in the plane) as beam 14 is scanned.

Thus, to improve production quality, focal plane distortion may need to be reduced or eliminated. Without such correction, the focus region would need to be sufficiently small and the resolution of the objective lens would need to be sufficiently high to ensure quality production. With the automatic, real-time reduction or correction of focal plane distortion as described herein, an objective lens with a relatively low resolution, such as a dry objection lens, can be used for two-photon stereolithography.

In an exemplary embodiment of the present invention, potential focal plane distortion is reduced or corrected by dynamically adjusting the distance between the expansion lens 21 and the focusing lens 23 in expander 20. This adjustment is automatically controlled by controller 38. The divergence of collimated beam 14B produced by expander 20 is dependent on the distance between lenses 21 and 23. The divergence of collimated bean 14B can thus be varied by adjusting this distance. The divergence of collimated beam 14B in turn affects the focal distance of the focal point from objective lens 30. Thus, by adjusting the distance between lenses 21 and 23 the focal distance can be varied to offset the effect of field curvature, and any other effects that cause focal plane distortion, so that the beam wais of focused beam 14C (or focal point) remains substantially in the focal plane 48 as beam 14C is scanned to successive scan positions. Generally, when beam 14 is scanned to a scan position where the beam waist is away from optical axis 50 of objective lens 30, the focal distance will need to be increased by a suitable amount to offset the effect of field curvature and to keep the beam waist remain in focal plane 48. The focal distance can be increased by increasing the divergence of the incident beam, collimated beam 14B.

The amount of increase of the divergence for a given location, and thus the required length of distance between lenses 21 and 23, can be initially estimated by calculation based on optics theory for the particular optical setup. The calculated lengths can be further fine tuned or verified by calibration. For example, the calibration may be carried out by visually inspecting an article produced using system 10, such as with an SEM imaging technique. When the distance is adjusted correctly during beam scanning, the produced article should have a shape closely resembling the input drawing. If the shape of the produced article is deformed in regions away from axis 50, the distance data will need to be further modified. The selected length values for different scan positions may be stored, such as in a memory (not separately shown) in controller 38, in association with the respective scan positions for later retrieval and use. The memory may also be separate from, but in communication with, controller 38, so that controller 38 can access the stored distance data during operation. In either case, controller 38 can control the adjustment of the distance in synchronization with the movement of scanner 26 based on the stored distance data and the current scan position.

For example, the distance data and the associated scan positions may be stored in a table format. The distance data may be presented as absolute length values or as differences from an initial distance. For instance, the initial distance may be a distance for producing an optimally collimated beam. The scan position may be defined or represented/expressed in different manners. For example, in some embodiments, the scan position may be defined by the scanner mirror positions. In other embodiments, the scan position may be defined by the direction of beam 14B such as relative to the optical axis of microscope 28 or objective lens 30. The scan positions may also be defined by the two-dimensional coordinates of the intercept of the beam axis and the focal plane 48. For example, if the direction of optical axis 50 is defined as the z-axis, the x-y coordinates of the intercept may be used to define the scan position of beam 14.

In one embodiment, to produce a 3D structure in a target material, a 3D drawing of the structure to be produced is broken down into component slices, lines and dots. The target material is first fixed in position to form a slice of the structure by scanning beam 14 using scanner 26 according to the input slice image and by synchronized adjustment of the distance between lenses 21 and 23 to maintain the beam waist within a plane that overlaps the desired slice during scanning. The target material is then repositioned to form the next slice of structure. This process can continue until the entire 3D structure is formed.

In one embodiment, the wavelength of beam 14 may be about 740 nm. The dry objective lens 30 may have a magnification factor of 20 and the microscope 28 may have a field of view of 400 μm by 400 μm. The spot size of the beam waist at the focal point may be about 2 μm or less. The depth of focus may be about 10 μm.

Target material 40 may be any suitable material selected for the particular application, as discussed herein.

Support 34 is controlled by controller 38 or another controller (not shown) to adjust the position of target 32 as appropriate. The positions may be adjusted based on user input or automatically according to a pre-programmed procedure and based on dynamic input received by controller 38.

The process can be monitored in real-time with camera 36. The images captured by camera 36 may be communicated to controller 38 for processing or analysis and may be used as input for controlling other components in the system.

The speed of beam scan across target 32 can be as high as 30 mm/s.

The scan height (along axial direction of the beam) can be as high as 30 mm.

The scan resolution of system 10 can be varied using different objective lenses and can be as high as 0.1×0.1×0.1 (in micron) with 100× magnification.

When beam 14 with a sufficient power (beam intensity) and suitable wavelength or spectrum is focused into the focus region of target material 40, two-photon absorption occurs with a high frequency and photochemical reactions such as photo-induced polymerization will proceed with a sufficiently high rate.

For instance, in a typical two-photon polymerization process, near-infrared (NIR) light with high peak power is focused on a photopolymer. The photopolymer includes photo-initiators that can form a radical when a single UV photon is absorbed and the absorbed photon energy excites an electron to initiate photo-chemical reaction. The resulting radical will cleave the double bonds of the unsaturated carbon bonds in the acryl groups of the monomers and oligomers, successively creating new radicals. This chain reaction is terminated when two chain radicals meet and react with each other. The same initiator can simultaneously absorb two coherent NIR photons and form the radical, as the combined photon energy from the two photons can also excite the electron to initiate the same photo-chemical reaction. The probability of two-photon absorption can be approximated by the following equation,

$${n}_{a} ∝ \frac{{δ}_{2} {P}_{ave}^{2}}{{τ}_{p} {f}_{p}^{2}} {( \frac{{NA}^{2}}{2 η c λ} )}^{2} , \qquad Equation ( 1 )$$

where nₐ is the probability that a certain fluorophore in the target material 40 simultaneously absorbs two photons during a single laser pulse, Pₐᵥₑ is the time average power of laser beam 14, δ₂ is the molecular cross-section of the fluorophore molecules in the target material 40, τₚ is the duration of each laser pulse, fₚ is the repetition rate of the laser,

$$η = \frac{h}{2 π}$$

(h being the Plank constant), λ is the excitation wavelength (or the single-photon absorption wavelength), c is the speed of light, and NA is the numerical aperture of objective lens 30.

As can be determined from the above equation, a consequence of two-photon absorption initiated photochemical reaction is that sufficient photo-chemical reaction can occur within a confined region, the focus region around the beam waist, to cause structural change within the focus region, but not outside the focus region because the probability of two-photon absorption outside the focus region is too low to cause significant structural change. The focus region in two-photon absorption is axially confined. That is, the focus region only extends along a small portion of the axis of the objective lens. Practically speaking, the probability of two-photon absorption/excitation falls off as the fourth power of the distance from the focal point of the objective lens, as the laser intensity itself has a quadratic dependence on axial distance. Typically, the volume of the focus region in two-photon absorption can be about 10⁻¹² cm³ or less. In contrast, the probability of single-photon absorption remains more stable over a large portion of the axis of the objective lens, as it is only a function of the laser intensity which is in turn linearly dependent on axial distance.

As a result of the two-photon absorption/excitation initiated photochemical reactions, a desired structural change will occur within the focus region of target material 40. The structural change can include chemical structural change, physical structural change, or both. The structural change can be visible or invisible to human eye. Because two-photon absorption only occurs with high probability in the focus region, no significant structural change will occur outside the focus region. By controlling the incidence direction of beam 14B relative to the target material 40, and thus the focus region in target material 40, 3-D structures can be produced. This process may be controlled by controller 38.

The axial movement of the focus region within target material 40 is accomplished by axially moving support 34 along the axial direction of the optical axis 50 of objective lens 30. The transversal movement of the focus region within target material 40 is accomplished by re-directing beam 14B using scanner 26 to scan the beam to successive scan positions. Additional transversal movement may be achieved by translational or rotational movement of support 34 in the plane transversal to the optical axis 50 of objective lens 30. In different embodiments, these movements may be effected differently. For example, axial movement may be effected by changing the focal plane of the beam, such as by adjusting or moving one or more optical focusing elements (e.g. microscope 28).

As now can be appreciated, system 10 can conveniently provide certain benefits. As no immersion liquid such as oil is needed to immerse the objective lens, the chance for contamination of focusing elements and the target material is reduced or minimized. As plane distortion is corrected dynamically, larger optical elements can be used thus increasing the sizes of devices that can be fabricated using system 10. The operation of system 10 is more flexible and easier as compared to some conventional devices. The scan speed and scan height are relative high in system 10, as compared to conventional two-photon lithography techniques where the objective lens are immersed in oil or water. The scan height in these conventional techniques is limited by the size of the oil droplets and the focal diameter of the objective lens and is typically less than about 1 mm. In system 10, the requirements for objective lens 30 are not as strict as for oil immersed objective lenses used in the conventional techniques. Thus, a wider selection of objective lenses may be used in system 10. When an AOM is used as the shutter, the shutter speed is faster. As expander 20 can provide automatic slice planarity control, relatively high magnification and resolution can be achieved without an oil immersion objective lens in two-photon lithography applications.

In addition, system 10 may be provided with laser focus wobble function, device stitching function, and device arraying. These functions make it possible to produce larger target devices by moving the support stage in the transversal directions.

System 10 can provide relatively high production throughput as compared to oil or water immersion based two-photon techniques.

System 10 may be modified while still retaining one or more of the benefits described herein. For example, laser beam properties may be varied in different embodiments and for different applications; and some components or devices may be located at an alternative position and still serve the same functional purposes. For instance, in different embodiments, camera 36 may be placed elsewhere and may receive reflected light from another point in the optical path of beam 14. Isolator 16 may be integrated with laser source 12. Shutter 18 may also be integrated with another optical component, such as laser source 12 or expander 20, or placed downstream of expander 20. Expander 20 may be provided as an integral unit or as an assembly of multiple units. Other suitable expander devices such as other suitable devices provide by Scanlab AG may be used as expander 20. Different optical path of beam 14 may be selected, using more or less mirrors and by placing mirrors or other deflecting or reflecting elements at different locations in the beam path. In different embodiments, the objective lens of the microscope may face different directions. As the objective lens is not immersed in a liquid such oil, the optical axis of the objective lens may be substantially aligned with the vertical direction, or a horizontal direction, or any other direction.

In a further example, system 10 may be operated in a manner different from the process described above.

Laser source 12 may also be replaced with another type of light source which can provide a beam of photons of suitable properties.

In different embodiments, any optical element of system 10, such as a lens, may be implemented in different manners. For example, each lens may be provided as a single lens, a compound lens, or a group of lenses integrated or combined to provide the desired function.

Additional optical elements, which may direct, focus or otherwise modify the beam properties or travel direction, may be placed in or along the beam path to perform a function desired for a given application. The additional optical elements may be placed at any suitable point of the beam path, and may be integrated with an element already shown in FIG. 1. For example, additional optical elements or features may be provided to improve the performance of the system, including aberration reduction or correction, where the aberration may be spherical, coma, or chromatic, or the like.

When reference is made to a plane such as a focal plane, it should be understood that in practical application, slight displacement of the beam waist from the focal plane at certain locations may be inevitable and may be permissible. For example, if the slight displacement does not result in unacceptable structural defects in the finished product, it may be tolerable. As can be understood, for practical purposes when the beam waist is sufficiently close to the focal plane, the structure formed by two-photon absorption induced polymerization may be substantially the same as, or even indistinguishable from, a structure produced with the beam waist strictly moved within the focal plane, due to the depth of focus for the particular optical setup. Thus, it should be understood that it is not necessary that the distance data be selected to restrict the movement of the beam waist to within a geometrical plane. Further, due to many practical limitations, it may not be possible to select distance data such that the beam waist always remains strictly within a geometrical plane. It therefore should be understood that, when a distance is selected to offset the field curvature effect at a given location to focus the beam at a location within the focal plane, it is sufficient that with the selected distance, the beam is focused such that the beam waist is within a tolerable distance from the ideal focal plane. Therefore, for the purposes of this invention, it should be understood that the locations of the beam waist are considered to be within a plane when they are generally within a plane or when they are sufficiently close to a plane so that their displacement from the plane has no material effect on the finished product.

An embodiment of the present invention such as a composition described herein may have various applications in many different fields. For instance, the compositions may be used for fabrication of 3D nanometer-scale (>100 nm) devices, and may be used in semiconductor industry (e.g. as direct-write lithography machine, for producing phase mask, for direct fabrication of optical components onto IC (integrated circuit) devices, for fabrication of sensors); in photonics (e.g. for processing photonic crystals and other optical structures, and quantum electronics); in wireless industry (e.g. for fabrication of resonators, waveguides, all-optics micro-transceiver devices); for fabrication of 3D nanometer-scale microelectromechanical system (MEMS) and nanoelectromechanical system (NEMS) devices; in rapid prototyping industry (e.g. for use in rapid prototyping systems and devices); in tissue engineering (e.g. for fabrication of tissue scaffold, for organ regeneration); in chemical and pharmaceutical industries (e.g. fabrication of substrates for the synthesis of chiral compounds), and the like.

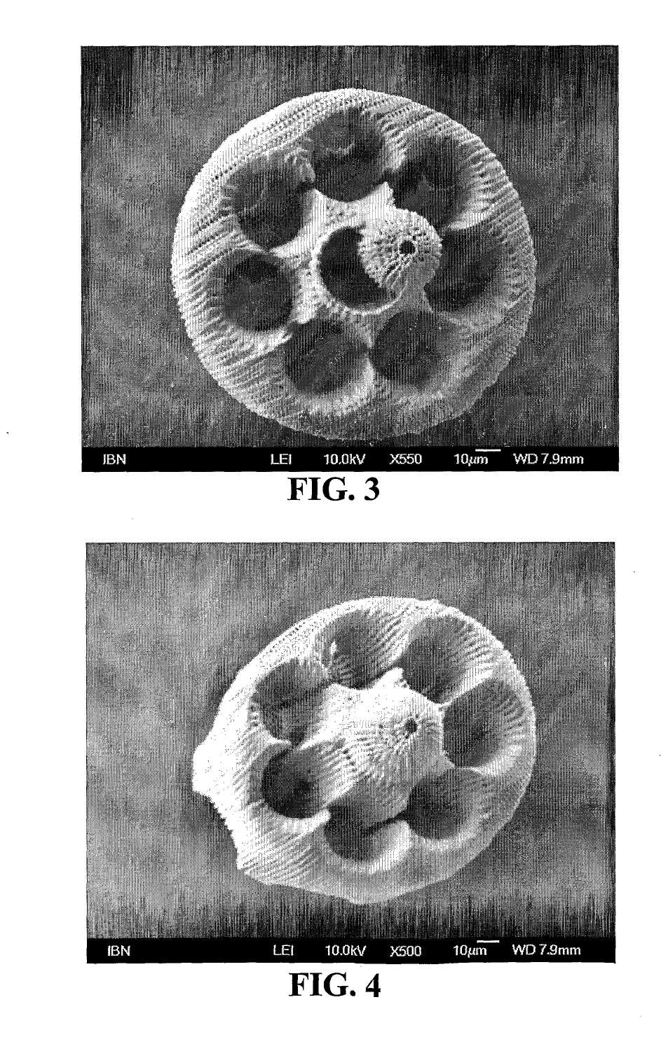

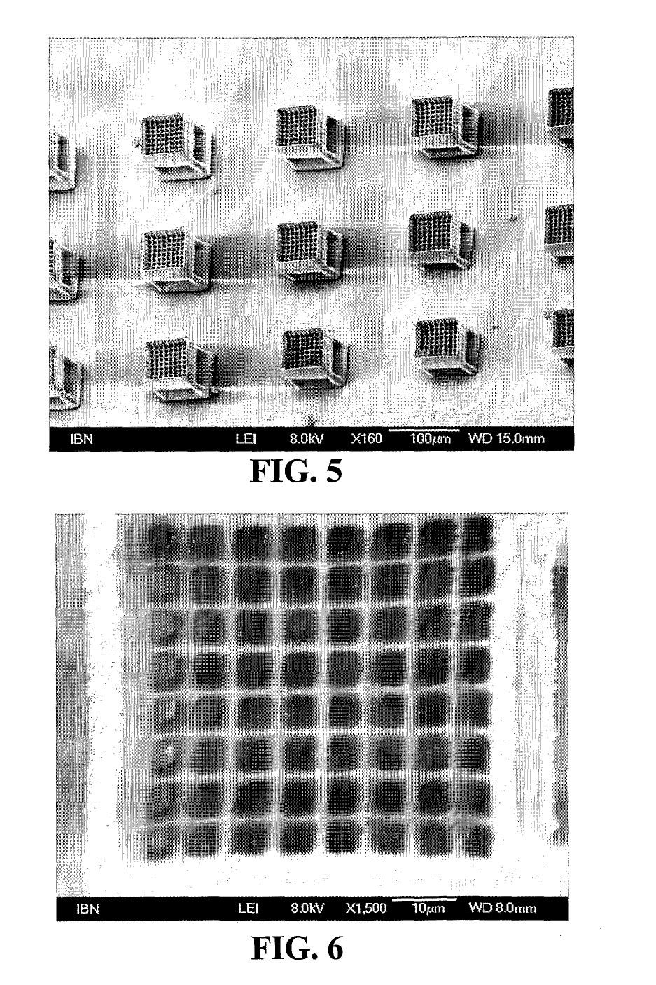

Sample articles and devices were fabricated by two-photon stereolithography using exemplary compositions described herein. SEM images of two sample products are shown in FIGS. 3, 4, 5 and 6. The sample products were formed with a laser light with a wavelength of about 710 nm and an average laser power of about 1 W.

Other features, benefits and advantages of the embodiments described herein not expressly mentioned above can be understood from this description and the drawings by those skilled in the art.

Of course, the above described embodiments are intended to be illustrative only and in no way limiting. The described embodiments are susceptible to many modifications of form, arrangement of parts, details and order of operation. The invention, rather, is intended to encompass all such modification within its scope, as defined by the claims.

1. A method of processing a material to form a three-dimensional article, comprising:
providing a photocurable material comprising a poly(meth)acrylate having a (meth)acrylate functionality of at least 3 and a molecular weight (MW) of at least 650, a urethane(meth)acrylate having a (meth)acrylate functionality of 2 to 4 and a MW of 400 to 10,000, a di(meth)acrylate made from bisphenol A or bisphenol F; and a photoinitiator;
focusing a beam of light to a focus region of said material to induce two-photon absorption in said focus region, and thus polymerization of said material in said focus region, a wavelength of said light being selected to induce said two-proton absorption in said material; and
scanning said beam across said material according to a pre-selected pattern so that said beam is focused to different pre-selected regions, to induce polymerization of said material at said pre-selected regions.

2. The method of claim 1, comprising removing a un-polymerized portion of said material from a polymerized portion of said material, thus forming said three-dimensional article.

3. The method of claim 1, wherein said material comprises 2 to 20 wt % of said poly(meth)acrylate, 20 to 60 wt % of said urethane(meth)acrylate, 20 to 80 wt % of said di(meth)acrylate, and 0.1 to 10 wt % of said photoinitiator.

4. The method of claim 3, wherein said poly(meth)acrylate has a MW in the range of 880 to 1200.

5. The method of claim 1, wherein said material comprises 5 to 18 wt % of said poly(meth)acrylate.

6. The method of claim 1, wherein said material comprises 20 to 50 wt % of said urethane(meth)acrylate.

7. The method of claim 1, wherein said material comprises 35 to 55% of said di(meth)acrylate.

8. The method of claim 1, wherein said material comprises 2 to 8 wt % of said photoinitiator.

9. The method of claim 1, wherein said material comprises 8 to 16 wt % of said poly(meth)acrylate, 25 to 45 wt % of said urethane(meth)acrylate, 40 to 50 wt % of said di(meth)acrylate, and 3 to 7 wt % of said photoinitiator.

10. The method of claim 1, wherein said di(meth)acrylate is monomeric or oligomeric.

11. The method of claim 10, wherein said di(meth)acrylate is a mixture of ethoxylated bisphenol A diacrylate and ethoxylated bisphenol A dimethacrylate.

12. The method of claim 1, wherein said scanning comprises scanning said beam according to a first pre-selected pattern to induce polymerization at pre-selected regions within a first layer, and subsequently scanning said beam according to a second pre-selected pattern to induce polymerization at pre-selected regions within a second layer.

13. The method of claim 12, wherein said first pattern and said second pattern are different.

14. The method of claim 12, wherein said first pattern and said second pattern are identical.

15. The method of claim 1, wherein said scanning is repeated to polymerize selected regions in more than two layers of said material.

16. The method of claim 1, wherein said beam has a spot size of about 2 μm or less at said focus region.

17. The method of claim 1, wherein said focus region has a volume of about 10⁻¹² cm³ or less.
